(19) United States
(12) Patent Application Publication
(10) Pub. No.: US 2022/0352392 A1
(43) Pub. Date: Nov. 3, 2022

(54) OPTICAL SENSOR WITH OPTICAL LAYER AND METHOD OF MANUFACTURE

(71) Applicants: Vanapong Kwangkaew, Wang Noi (TH); Sanjay Mitra, Colorado Springs, CO (US); Sirirat Silapapipat, Ladroad (TH)

(72) Inventors: Vanapong Kwangkaew, Wang Noi (TH); Sanjay Mitra, Colorado Springs, CO (US); Sirirat Silapapipat, Ladroad (TH)

(21) Appl. No.: 17/721,257

(22) Filed: Apr. 14, 2022

Related U.S. Application Data
(60) Provisional application No. 63/176,270, filed on Apr. 17, 2021.

(51) Int. Cl. H01L 31/0203

(52) U.S. Cl. CPC H01L 31/0203

(57) ABSTRACT

An optical sensor comprising a substrate. a silicon layer having an optical sensor. light transmissive material covering at least portions of the silicon layer, the optical sensor and the substrate; and an optical layer positioned above the light transmissive material. In some embodiments the optical layer can be a light filtering layer adapted and configured to selectively reflect, absorb or prohibit passage of light in a desired frequency range.

### CROSS REFERENCE TO RELATED APPLICATIONS

This application claims priority under 35 U.S.C. § 119(e) from earlier filed U.S. Provisional Application Ser. No. 63/176,270, filed Apr. 17, 2021. The entirety of the above-listed provisional application is incorporated herein by reference.

### BACKGROUND

### Technical Field

The present device relates to the field of optical sensor and methods of manufacture therefor.

### Background

FIG. 1 depicts a conventional optical sensor 100. As depicted, the optical sensor 100 consists of a substrate layer 102 with a silicon chip 104 in contact with a top surface of the substrate layer 102. A sensing area 106 is coupled with the silicon chip 104 and the silicon chip is coupled with the substrate 102 via one or more electrical couplings 108. The substrate 102, silicon chip 104, sensing area 106 and electrical couplings 108 are covered with a light transmissive (optically inert or substantially optically inert) material 110. In operation, this allows transmitted light within various spectra (visible light 112, UV light 114 and/or infrared light 116) to pass through the light transparent material 110 and be detected by the sensing area 106. However, it is not optimal for the sensing area to be responsive to all light or all light within the vicinity of the optical sensor 100. Therefore, what is needed is an optical sensor with an optical layer and method of manufacture therefor.

### BRIEF DESCRIPTION OF THE DRAWINGS

Further details of the present device are explained with the help of the attached drawings in which:

FIG. 1 depicts a prior art embodiment of an optical sensor.

FIG. 2 depicts an embodiment of an optical sensor with a light filtering optical layer.

FIG. 3 depicts an embodiment of an optical sensor with a light diffusing layer.

FIG. 4 depicts an embodiment of an optical sensor with a light polarizing layer.

FIG. 5 depicts an embodiment of an optical sensor with an optical layer and an aperture.

FIG. 6 depicts an embodiment of a method of manufacture of the optical sensor of FIGS. 1-5.

### DETAILED DESCRIPTION

As used in the description herein and throughout the claims that follow, “a”, “an”, and “the” includes plural references unless the context clearly dictates otherwise. Also, as used in the description herein and throughout the claims that follow, the meaning of “in” includes “in” and “on” unless the context clearly dictates otherwise.

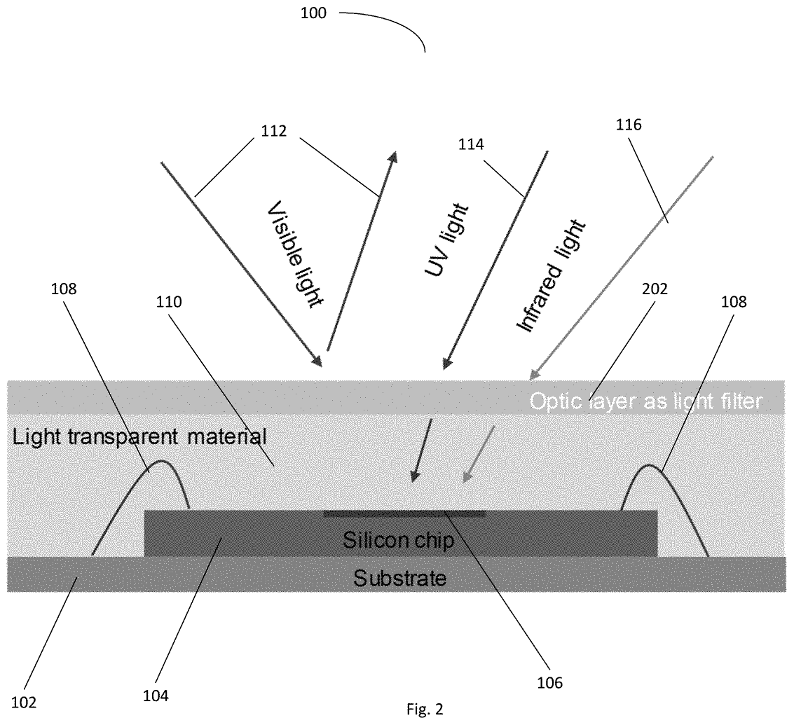

FIG. 2 depicts an embodiment of an optical sensor 100 with a light filtering optical layer 202. As depicted, the optical sensor 100 can comprise a substrate layer 102 with a silicon chip 104 in contact with a top surface of the substrate layer 102. A sensing area 106 can be coupled and/or integral with the silicon chip 104 and the silicon chip can be coupled with the substrate 102 via one or more electrical couplings 108. The substrate 102, silicon chip 104, sensing area 106 and electrical couplings 108 can be covered with a light transmissive (optically inert or substantially optically inert) material 110. In the embodiment depicted in FIG. 2, the sensor 100 can comprise a light filtering optical layer 202 above the light transmissive material 110. In some embodiments the light filtering optical layer 202 can comprise any known convenient and/or desired material that is adapted and/or configured to selectively reflect, absorb and/or prohibit passage through the light filtering optical layer 202 of light having any desired wavelength and/or frequency and/or wavelength range and/or frequency range and/or wavelength ranges and/or frequency ranges. In operation, light of only desired wavelengths(s) and/or frequency(ies) can pass through the optical layer 202 and reach and/or be detected by the sensing area 106.

In some embodiments the light filtering optical layer 202 can be in direct contact with the light transmissive material 110. However, in alternate embodiments, the light filtering optical layer 202 can be located above the light transmissive material 110 and one or more additional layers or gaps can be positioned between the light transmissive material 110 and the light filtering optical layer 202. Moreover, in some embodiments, the light filtering optical layer 202 can be continuous above the light transmissive material 110. However, in alternate embodiments, the light filtering optical layer 202 can be other than continuous and/or be periodically positioned above the light transmissive material 110.

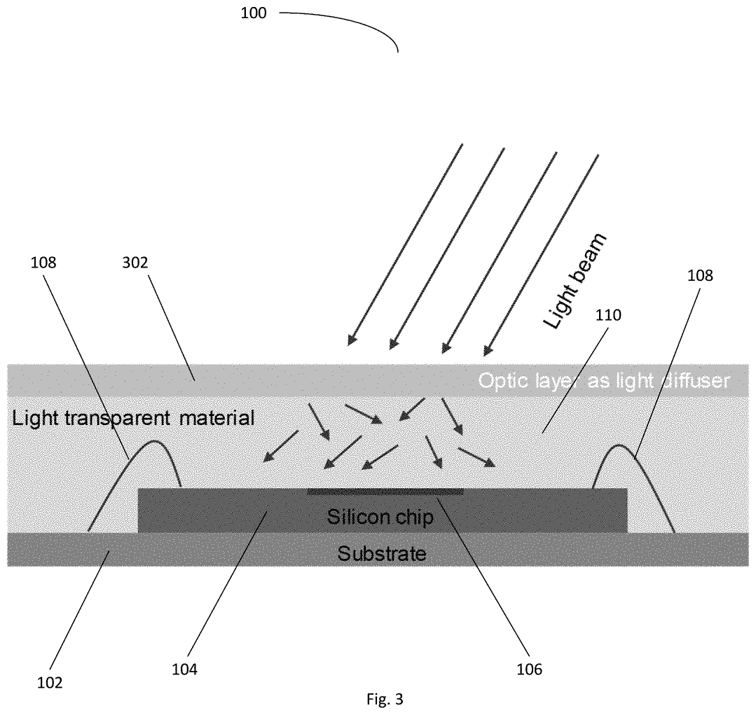

FIG. 3 depicts an embodiment of an optical sensor with a light diffusing layer 302. As depicted, the optical sensor 100 can comprise a substrate layer 102 with a silicon chip 104 in contact with a top surface of the substrate layer 102. A sensing area 106 can be coupled and/or integral with the silicon chip 104 and the silicon chip can be coupled with the substrate 102 via one or more electrical couplings 108. The substrate 102, silicon chip 104, sensing area 106 and electrical couplings 108 can be covered with a light transmissive (optically inert or substantially optically inert) material 110. In the embodiment depicted in FIG. 3, the sensor 100 can comprise a light diffusing optical layer 302 above the light transmissive material 110. In some embodiments the light diffusing optical layer 302 can comprise any known convenient and/or desired material that is adapted and/or configured to selectively diffuse and/or scatter light having any desired wavelength and/or frequency and/or wavelength range and/or frequency range and/or wavelength ranges and/or frequency ranges reaching the light diffusing optical layer 302. In operation, light of only desired wavelength(s) and/or frequency(ies) can pass through the light diffusing optical layer 302 and reach and/or be detected by the sensing area 106.

In some embodiments the light diffusing optical layer 302 can be in direct contact with the light transmissive material 110. However, in alternate embodiments, the light diffusing optical layer 302 can be located above the light transmissive material 110 and one or more additional layers or gaps can be positioned between the light transmissive material 110 and the light diffusing optical layer 302. Moreover, in some embodiments, the light diffusing optical layer 302 can be continuous above the light transmissive material 110. However, in alternate embodiments, the light diffusing optical layer 302 can be other than continuous and/or be periodically positioned above the light transmissive material 110.

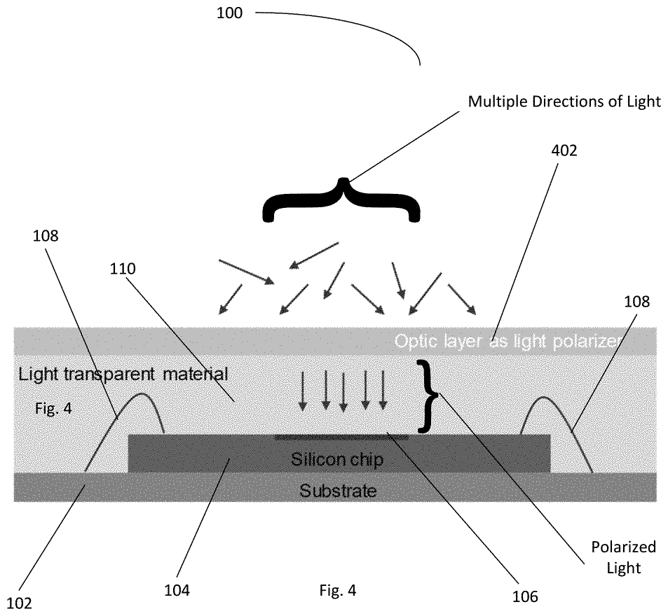

FIG. 4 depicts an embodiment of an optical sensor with a light polarizing optical layer 402. As depicted, the optical sensor 100 can comprise a substrate layer 102 with a silicon chip 104 in contact with a top surface of the substrate layer 102. A sensing area 106 can be coupled and/or integral with the silicon chip 104 and the silicon chip can be coupled with the substrate 102 via one or more electrical couplings 108. The substrate 102, silicon chip 104, sensing area 106 and electrical couplings 108 can covered with a light transmissive (optically inert or substantially optically inert) material 110. In the embodiment depicted in FIG. 4, the sensor 100 can comprise a light polarizing optical layer 402 above the light transmissive material 110. In some embodiments the light polarizing optical layer 402 can comprise any known convenient and/or desired material that is adapted and/or configured to selectively reflect, diffuse and/or scatter light having an orientation/polarization other than a desired orientation/polarization and/or orientations/polarizations relative to the light polarizing optical layer 402. In operation, light of only desired polarization(s) can pass through the light polarizing optical layer 402 and reach and/or be detected by the sensing area 106.

In some embodiments the light polarizing optical layer 402 can be in direct contact with the light transmissive material 110. However, in alternate embodiments, the light polarizing optical layer 402 can be located above the light transmissive material 110 and one or more additional layers or gaps can be positioned between the light transmissive material 110 and the light polarizing optical layer 402. Moreover, in some embodiments, the light polarizing optical layer 402 can be continuous above the light transmissive material 110. However, in alternate embodiments, the light polarizing optical layer 402 can be other than continuous and/or be periodically positioned above the light transmissive material 110.

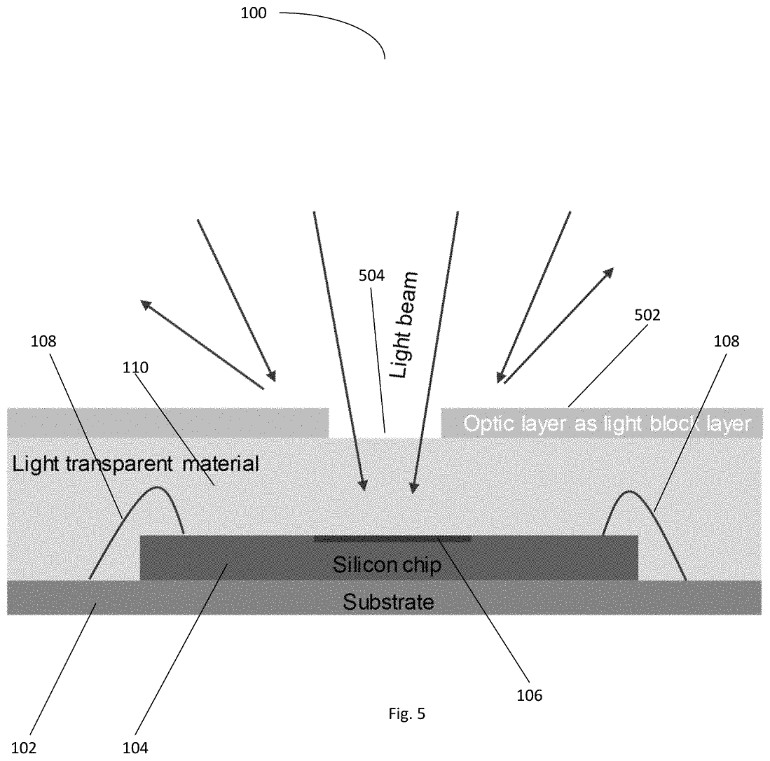

FIG. 5 depicts an embodiment of an optical sensor with an optical layer 502 and an aperture 504. As depicted, the optical sensor 100 can comprise a substrate layer 102 with a silicon chip 104 in contact with a top surface of the substrate layer 102. A sensing area 106 can be coupled and/or integral with the silicon chip 104 and the silicon chip can be coupled with the substrate 102 via one or more electrical couplings 108. The substrate 102, silicon chip 104, sensing area 106 and electrical couplings 108 can covered with a light transmissive (optically inert or substantially optically inert) material 110. In the embodiment depicted in FIG. 5, the sensor 100 can comprise an optical layer 502 with an aperture 504 above the light transmissive material 110. In some embodiments, the optical layer can be any one of a light filtering optical layer 202, a light diffusing optical layer 302, a light polarizing optical layer 402 and/or any other known, convenient and/or desired light blocking material.

In some embodiments the optical layer 502 can be in direct contact with the light transmissive material 110. However, in alternate embodiments, the optical layer 502 can be located above the light transmissive material 110 and one or more additional layers or gaps can be positioned between the light transmissive material 110 and the optical layer 502. In operation, light approaching the optical sensor 100 can pass through the aperture 504 and reach the sensing area 106. Additionally, in some embodiment, the aperture 504 can be filled or partially filled with an alternate optical layer material other than the material comprising the optical layer 502.

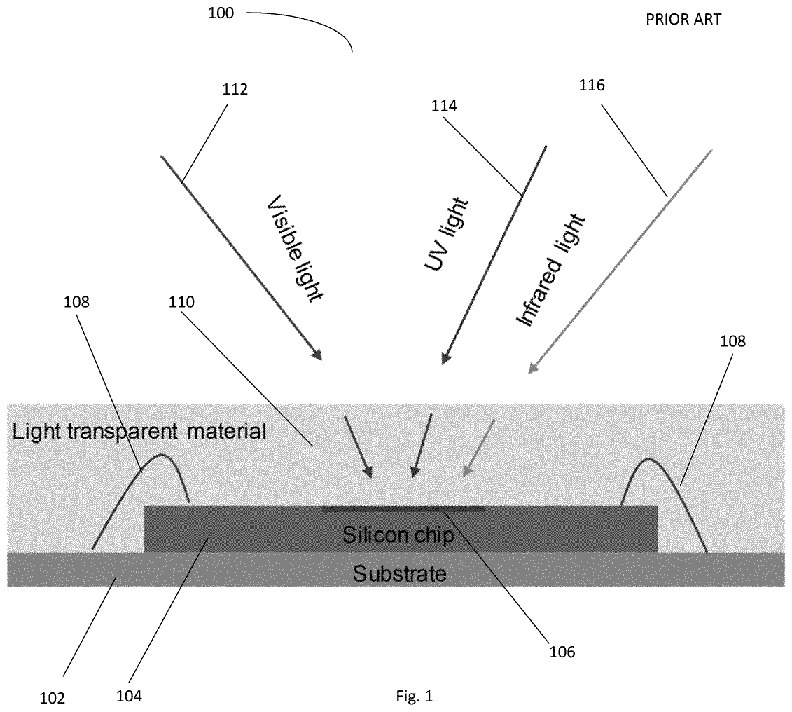

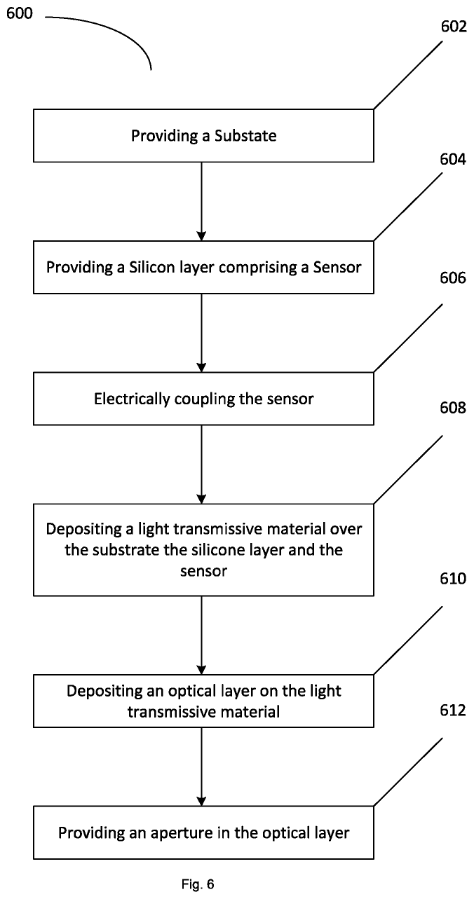

FIG. 6 depicts an embodiment of a method of manufacture of the optical sensor of FIGS. 1-5. In some embodiments, the optical sensor 100 can comprise the steps of providing a substrate in step 602, providing a silicon layer 604 having a sensor area, electrically coupling the silicon layer with the substrate in step 606 then depositing a light transmissive (optically inert) material over the substrate and silicon layer in step 608. Depositing an optical layer on or above the light transmissive material in step 610 then in some embodiments providing an aperture in the optical layer in step 612.

Although exemplary embodiments of the invention have been described in detail and in language specific to structural features and/or methodological acts above, it is to be understood that those skilled in the art will readily appreciate that many additional modifications are possible in the exemplary embodiments without materially departing from the novel teachings and advantages of the invention. Moreover, it is to be understood that the subject matter defined in the appended claims is not necessarily limited to the specific features or acts described above. Accordingly, these and all such modifications are intended to be included within the scope of this invention construed in breadth and scope in accordance with the appended claims.

What is claimed:

1. An optical sensor comprising:
a substrate;
a silicon layer having an optical sensor;
light transmissive material covering at least portions of said silicon layer, said optical sensor and said substrate; and
an optical layer positioned above said light transmissive material.

2. The sensor of claim 1, wherein said optical layer is a light filtering layer adapted and configured to selectively reflect, absorb or prohibit passage of light in a desired frequency range.

3. The sensor of claim 2, wherein said optical layer is in direct contact with the light transmissive material.

4. The sensor of claim 3 wherein said optical layer is substantially continuous above the light transmissive layer.

5. The light sensor of claim 3, wherein said optical layer is non-continuous above the light transmissive layer.

6. The light sensor of claim 5, wherein said optical layer is periodically positioned above the light transmissive layer.

7. The sensor of claim 1, wherein said optical layer is a light diffusing layer.

8. The sensor of claim 7, wherein said optical layer is in direct contact with the light transmissive material.

9. The sensor of claim 7 wherein said optical layer is substantially continuous above the light transmissive layer.

10. The light sensor of claim 7, wherein said optical layer is non-continuous above the light transmissive layer.

11. The light sensor of claim 10, wherein said optical layer is periodically positioned above the light transmissive layer.

12. The sensor of claim 1, wherein said optical layer is a light polarizing layer.

13. The sensor of claim 12, wherein said optical layer is in direct contact with the light transmissive material.

14. The sensor of claim 13 wherein said optical layer is substantially continuous above the light transmissive layer.

15. The light sensor of claim 13, wherein said optical layer is non-continuous above the light transmissive layer.

16. The light sensor of claim 15, wherein said optical layer is periodically positioned above the light transmissive layer.

17. The light sensor of claim 1, wherein said optical layer is a light-blocking layer having an aperture positioned substantially above said optical sensor.

18. The sensor of claim 17, wherein said optical layer is in direct contact with the light transmissive material.

19. The sensor of claim 17 wherein said optical layer is substantially continuous above the light transmissive layer.

20. The light sensor of claim 17, wherein said optical layer is non-continuous above the light transmissive layer.

21. The light sensor of claim 20, wherein said optical layer is periodically positioned above the light transmissive layer.

22. A method of manufacture of an optical sensor comprising the steps of:
providing a substrate;
providing a silicon layer having a sensor area;
electrically coupling the silicon layer with the substrate; and
depositing a light transmissive material over the substrate and silicon layer.

23. The method of claim 22, further comprising the step of depositing an optical layer above the light transmissive material

24. The method of claim 22, further comprising the step of depositing an optical layer on the light transmissive material.

25. The method of claim 22, further comprising the step of providing an aperture in the optical layer.
